(19) United States
(12) Patent Application Publication
(10) Pub. No.: US 2015/0214010 A1
(43) Pub. Date: Jul. 30, 2015

(54) PLASMA ENHANCED CHEMICAL VAPOR DEPOSITION DEVICE

(71) Applicants: Char Lie HONG, (US); Man Ho LEE, (US); BMC CO., LTD., Seongnam-si (KR)

(72) Inventors: Charlie Hong, Seongnam-si (KR); Man Ho Lee, Yongin-si (KR)

(73) Assignees: BMC CO., LTD., Seongnam-si (KR); Man Ho LEE, Yongin-si (KR); Charlie HONG, Seongnam-si (KR)

(21) Appl. No.: 14/430,219

(22) PCT Filed: Sep. 25, 2013
(86) PCT No.: PCT/KR2013/008578

§ 371 Date: Mar. 21, 2015

(30) Foreign Application Priority Data
Sep. 26, 2012 (KR) 10-2012-0107139

(51) Int. Cl. H01J 37/32; C23C 16/458; C23C 16/54; C23C 16/44; C23C 16/503; C23C 16/52

(52) U.S. Cl. CPC H01J 37/3266; C23C 16/503; C23C 16/52; C23C 16/545; C23C 16/4412; C23C 16/458; H01J 37/32449; H01J 37/32816; C23C 16/4401; H01J 2237/3321

(57) ABSTRACT

A plasma enhanced chemical vapor deposition apparatus is disclosed. The plasma enhanced chemical vapor deposition apparatus includes a pair of magnetic field generating unit arranged to face each other with a gap therebetween; a pair of facing electrodes arranged to face each other between the pair of magnetic field generating units; a gas supply unit configured to supply a reaction gas into a space between the pair of facing electrodes; and a precursor supply unit configured to supply a precursor into the space between the pair of facing electrodes. A facing magnetic field may be formed between the pair of magnetic field generating units.

### FIELD OF THE INVENTION

The present disclosure relates to a plasma enhanced chemical vapor deposition apparatus.

### BACKGROUND OF THE INVENTION

In a manufacturing process of a liquid crystal display, an active layer and an ohmic contact layer of a thin film transistor, an insulating film for insulating a data line and a gate line, a protection film for insulating the data line and the gate line from pixel electrodes, and so forth are formed by a physical vapor deposition method such as sputtering deposition or by a chemical vapor deposition method such as plasma enhanced chemical vapor deposition (PECVD).

Among these methods, the plasma enhanced chemical vapor deposition is a method in which a reaction gas required for vapor deposition is injected into a chamber under a vacuum; if a required pressure and a required substrate temperature are set, a super high frequency wave is applied to an electrode from a power supply device to thereby excite the reaction gas into plasma and ionize a precursor; and a thin film is formed as the ionized precursor and a part of the reaction gas in the plasma state react with each other physically or chemically and are deposited on the substrate.

In order to improve deposition efficiency for the thin film in the plasma enhanced chemical vapor deposition, it is required to increase plasma density by maintaining the plasma generated in the vacuum chamber with the help of, e.g., a magnetic field, thus enhancing an ionization rate of the precursor and a coupling rate between the ionized precursor and a part of the reaction gas in the plasma state, i.e., reactivity of the matters. Further, it is also required to suppress contamination of the electrode with the precursor, thus allowing plasma to be generated smoothly.

A conventional plasma enhanced chemical vapor deposition apparatus, however, has a drawback in that plasma density is low and a precursor may be introduced to an electrode, resulting in contamination of the electrode with the precursor. Thus, the conventional plasma enhanced chemical vapor deposition apparatus could not have high thin film deposition efficiency.

### DISCLOSURE OF THE INVENTION

### Problems to be Solved by the Invention

In view of the foregoing problems, an illustrative embodiment provides a plasma enhanced chemical vapor deposition apparatus capable of obtaining high deposition efficiency for a thin film by increasing plasma density while suppressing contamination of an electrode that might be caused by introduction of a precursor to the electrode.

### Means for Solving the Problems

In accordance with the illustrative embodiment, there is provided an A plasma enhanced chemical vapor deposition apparatus for depositing a thin film on a surface of a coating target in a vacuum chamber, including a pair of magnetic field generating units arranged to face each other with a gap therebetween; a pair of facing electrodes arranged to face each other between the pair of magnetic field generating units; a gas supply unit configured to supply a reaction gas into a space between the pair of facing electrodes; and a precursor supply unit configured to supply a precursor into the space between the pair of facing electrodes, wherein a facing magnetic field is formed between the pair of magnetic field generating units.

In the present disclosure, wherein each of the pair of magnetic field generating units includes comprises an internal polarity section and an external polarity section surrounding the internal polarity section, and the polarity of the external polarity section is opposite to the polarity of the internal polarity section.

In the present disclosure, wherein the gap is a spatial interval set to allow the facing magnetic field, which provides a rotational force for an electron, to be formed between the pair of magnetic field generating units arranged to face each other.

In the present disclosure, a central magnetic field generating unit between the pair of facing electrodes, wherein the central magnetic field generating unit is configured to form a magnetic field between itself and each of the pair of magnetic field generating units.

### Effect of the Invention

In accordance with the illustrative embodiment, the plasma enhanced chemical vapor deposition apparatus generates the facing magnetic fields between the pair of magnetic field generating units or between the central magnetic field generating unit and the pair of magnetic field generating units. Further, the plasma enhanced chemical vapor deposition apparatus also generates lateral magnetic fields between the external polarity section and the internal polarity section of each magnetic field generating unit. The facing magnetic fields and the lateral magnetic fields allow electrons to make rotational motion and hopping motion infinitely. Accordingly, in the present disclosure, even when a thin film deposition process is performed in the vacuum chamber set to a vacuum level lower than that in a conventional apparatus while inputting the precursors and the reaction gas in smaller amounts as compared to those in the conventional apparatus, thin film deposition efficiency equivalent to or higher than that obtained in the conventional apparatus can be still acquired. That is, in accordance with the present disclosure, the required amounts of the precursors and the reaction gas can be reduced, and a load on a vacuum pump can be reduced. Thus, a more economic and efficient thin film deposition process can be performed.

### BRIEF DESCRIPTION OF THE DRAWINGS

FIG. 1 is a conceptual diagram of a plasma enhanced chemical vapor deposition apparatus in accordance with an illustrative embodiment;

FIG. 2 is a conceptual diagram for describing a magnetic field generated in the plasma enhanced chemical vapor deposition apparatus in accordance with the illustrative embodiment;

FIG. 3 is a conceptual diagram for describing electron movement caused by the magnetic field generated in the plasma enhanced chemical vapor deposition apparatus in accordance with the illustrative embodiment;

FIG. 4 is a conceptual diagram illustrating electron movement when the part A of FIG. 3 is viewed obliquely from the side;

FIG. 5 is a conceptual diagram for describing flows of a reaction gas and a precursor in the plasma enhanced chemical vapor deposition apparatus in accordance with the illustrative embodiment;

FIGS. 6(a), 6(b) and 6(c) are conceptual diagrams for describing various examples of facing electrodes;

FIGS. 7(a) and 7(b) are conceptual diagrams for describing various examples of an external polarity section and an internal polarity section;

FIG. 8 is a conceptual diagram for describing a magnetic field generated by another example of a central magnetic field generating unit;

FIG. 9 is a conceptual diagram for illustrating another example of a moving unit;

FIG. 10(a) is a conceptual diagram for describing magnetic pole arrangement of a central magnetic field generating unit and a pair of magnetic field generating units of FIG. 2; and

FIG. 10(b) is a conceptual diagram for describing magnetic pole arrangement of the central magnetic field generating unit and a pair of magnetic field generating units of FIG. 8.

### DETAILED DESCRIPTION OF THE INVENTION

Hereinafter, illustrative embodiments and examples will be described in detail so that inventive concept may be readily implemented by those skilled in the art. However, it is to be noted that the present disclosure is not limited to the illustrative embodiments and examples but can be realized in various other ways. In drawings, parts not directly relevant to the description are omitted to enhance the clarity of the drawings, and like reference numerals denote like parts through the whole document.

Through the whole document, the term “on” that is used to designate a position of one element with respect to another element includes both a case that the one element is adjacent to the another element and a case that any other element exists between these two elements.

Through the whole document, the term “comprises or includes” and/or “comprising or including” used in the document means that one or more other components, steps, operation and/or existence or addition of elements are not excluded in addition to the described components, steps, operation and/or elements unless context dictates otherwise. The term “about or approximately” or “substantially” are intended to have meanings close to numerical values or ranges specified with an allowable error and intended to prevent accurate or absolute numerical values disclosed for understanding of the present disclosure from being illegally or unfairly used by any unconscionable third party. Through the whole document, the term “step of” does not mean “step for”.

Through the whole document, the term “combination of” included in Markush type description means mixture or combination of one or more components, steps, operations and/or elements selected from the group consisting of components, steps, operation and/or elements described in Markush type and thereby means that the disclosure includes one or more components, steps, operations and/or elements selected from the Markush group.

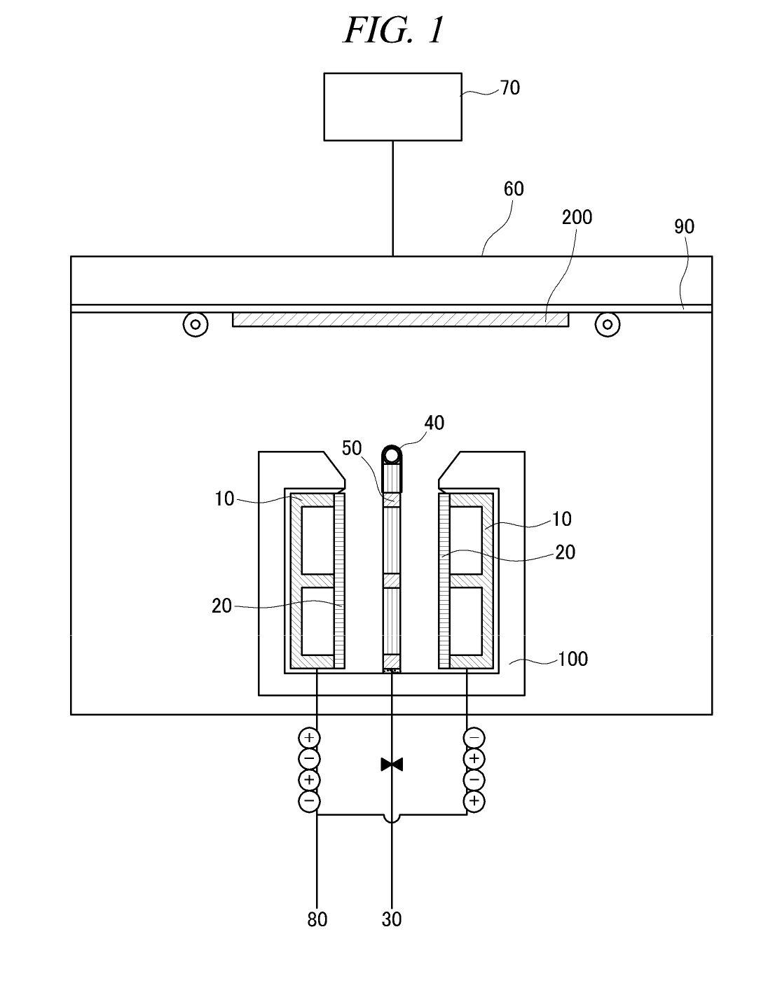

Further, in the following description of illustrative embodiments, terms related to a direction or a position (upper side, lower side, up and down directions, etc.) are defined with respect to the arrangement state of individual components shown in drawings. For example, the “upper side” and the “lower side” may be defined as the upper side and the lower side when viewed from FIG. 1, that is, the “left side” and the “right side” on a paper plane. However, it should be noted that when the illustrative embodiment is practically applied, the components may be arranged in various directions with the upper side and the lower side reversed, for example.

Below, illustrative embodiments and examples of the present disclosure will be described in detail.

First, a plasma enhanced chemical vapor deposition apparatus in accordance with an illustrative embodiment of the present disclosure (hereinafter, referred to as “the present plasma enhanced chemical vapor deposition apparatus”) will be described.

The present plasma enhanced chemical vapor deposition apparatus includes a pair of magnetic field generating units 10.

By way of non-limiting example, the pair of magnetic field generating units 10 may be implemented by a multiple number of magnets.

The pair of magnetic field generating units 10 may be arranged to face each other with a certain interval therebetween.

Plasma is generated as a gas is dissociated into positive ions and electrons by a direct current, an alternating current, a super high frequency wave, or the like. The plasma can be maintained by a magnetic field or the like.

A magnetic field generated by the pair of magnetic field generating units 10 applies a force according to the Fleming's left hand rule to the electrons generated from a reaction gas 31 dissociated by a super high frequency power supply or the like, thus making the electrons move continuously. Through this mechanism, by ionizing the reaction gas 31 continuously, the reaction gas 31 can be maintained in the plasma state.

Referring to FIGS. 1 to 9, the pair of magnetic field generating units 10 may be disposed within a mounting unit 100.

Facing magnetic fields 300A are formed between the pair of magnetic field generating units 10.

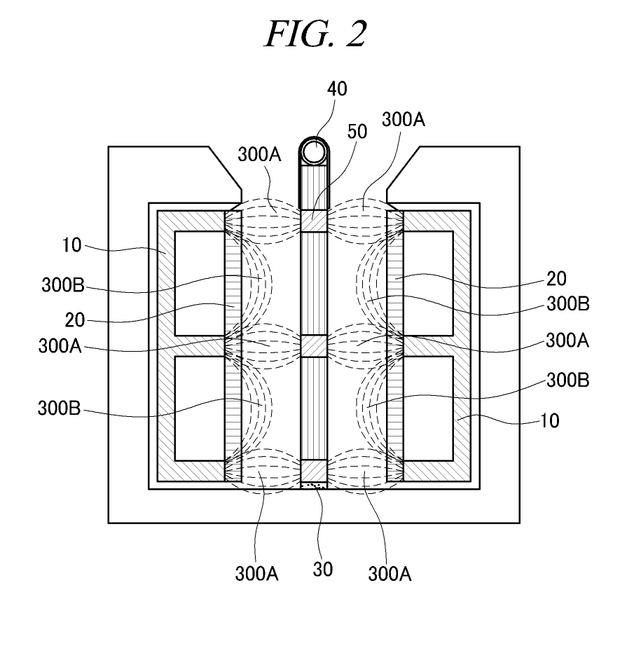

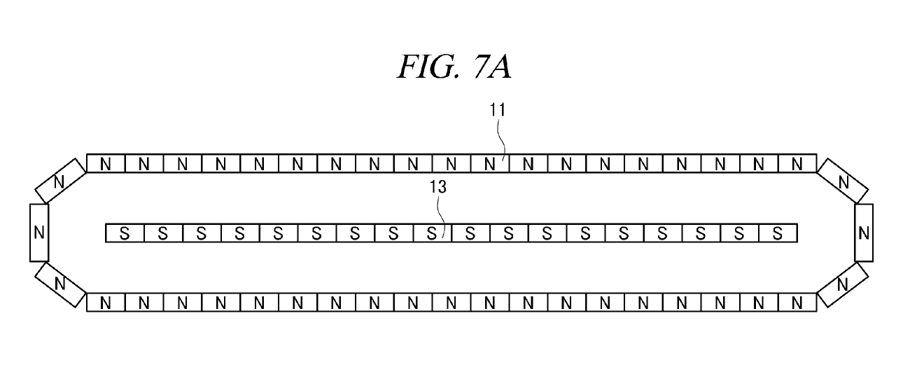

The facing magnetic fields 300A may be formed only by the single pair of magnetic field generating units 10, or by the single pair of magnetic field generating units 10 and a central magnetic field generating unit 50, as illustrated in FIGS. 2 and 8.

The pair of magnetic field generating units 10 may be arranged such that opposite magnetic poles face each other.

In such a configuration, the facing magnetic fields 300A may be formed only by the pair of magnetic field generating units 10.

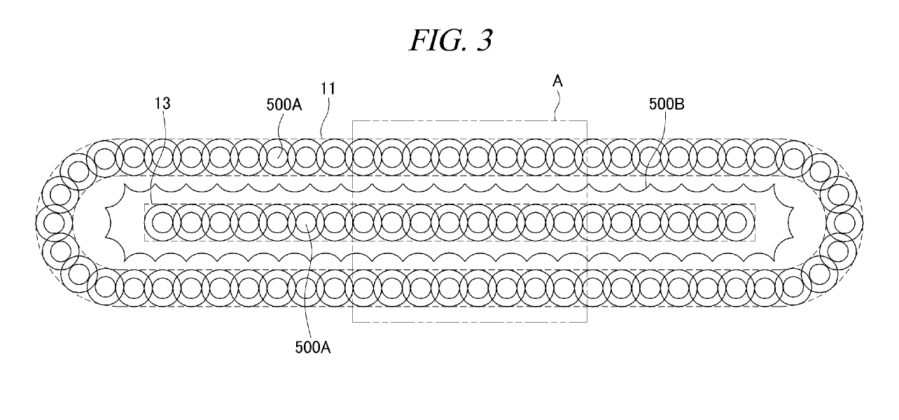

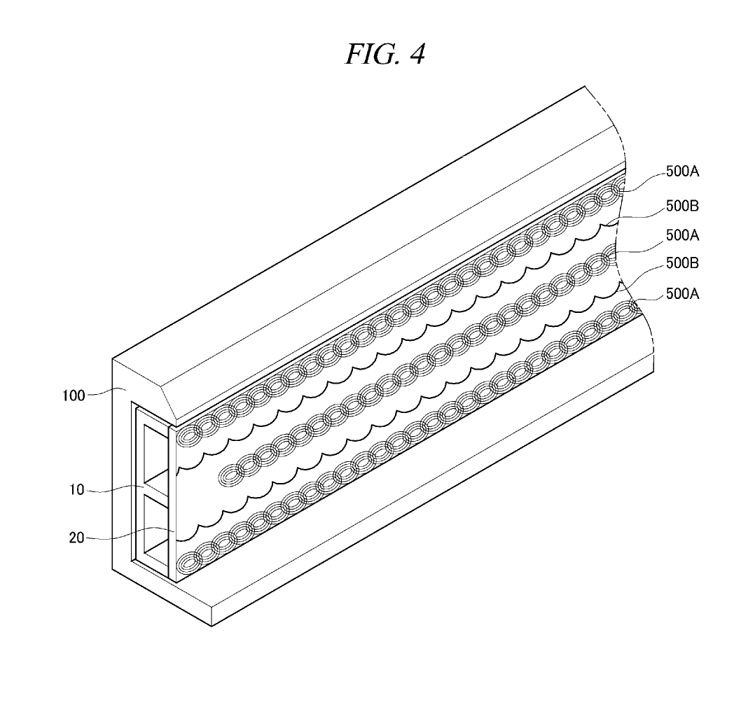

Referring to FIGS. 3 and 4, the facing magnetic fields 300A apply forces to the electrons generated from the reaction gas 31 in a direction perpendicular to the facing magnetic fields 300A according to the Fleming's left hand rule, thus allowing the electrons make rotational motions 500A on the surfaces of the facing electrodes 20.

As the electrons make the rotational motions 500A, the reaction gas 31 is continuously ionized into plasma. Accordingly, plasma density increases. Due to the plasma of such high density, reactivity of the matters increases, so that ionization of precursors 41 and coupling between a part of the reaction gas 31 in the plasma state and the ionized precursors 41 may be maximized. Thus, deposition efficiency for the deposition of the precursors 41 and the reaction gas 31 on a coating target 200 may be ameliorated.

Accordingly, in the present plasma enhanced chemical vapor deposition apparatus, even when a thin film deposition process is performed in the vacuum chamber 60 set to a vacuum level lower than that in a conventional apparatus while inputting the precursors 41 and the reaction gas 31 in smaller amounts as compared to those in the conventional apparatus, thin film deposition efficiency equivalent to or higher than that obtained in the conventional apparatus can be still acquired. That is, in accordance with the present disclosure, the required amounts of the precursors 41 and the reaction gas 31 can be reduced, and a load on a vacuum pump 60 can be reduced. Thus, a more economic and efficient thin film deposition process can be performed.

Each of the pair of magnetic field generating units may include an internal polarity section 13; and an external polarity section 11 surrounding the internal polarity section 13. The external polarity section 11 may have polarity opposite to that of the internal polarity section 13.

Referring to FIGS. 2 and 8, lateral magnetic fields 300B are generated between the external polarity section 11 and the internal polarity section 13. These lateral magnetic fields 300B apply, as depicted in FIGS. 3 and 4, forces to the electrons generated from the reaction gas 31 in a direction perpendicular to the lateral magnetic fields 300B according to the Fleming's left hand rule, thus allowing the electrons to make a hopping motion 500B on the surface of each facing electrode 20.

As discussed above, since the plasma accelerates the ionization and the coupling of matters, if the plasma density increases, an ionization rate of the precursors 41 may be increased, and a coupling rate between a part of the reaction gas 31 in the plasma state and the ionized precursors 41 may be increased. As a result, the deposition efficiency for the deposition of the precursors 41 and the reaction gas on the coating target 200 can be increased. That is, in order to improve the thin film deposition efficiency, various magnetic fields need to be formed to increase the density of the plasma, thus allowing the reaction gas to be continuously ionized into the plasma state.

To this end, in the present disclosure, magnetic fields are formed in various ways to allow the electrons to make various motions for the continuous ionization of the reaction gas 31. That is, in accordance with the present disclosure, not only the facing magnetic files 300A but also the lateral magnetic files 300B are formed between the external polarity section 11 and the internal polarity section 13, as illustrated in FIGS. 2 and 8. In this way, by generating the various magnetic fields, the electrons are made to make various motions, so that plasma density can be increased. As a consequence, the efficiency in the deposition of the precursors 41 and the reaction gas 31 on the coating target 200 can be enhanced.

Referring to FIGS. 3 and 4, the lateral magnetic fields 300B are formed and the electrons are activated through the hopping motion 500B. The electrons activated through the hopping motion 500B may contribute to the ionization of the reaction gas 31 in cooperation with the electrons activated through the rotational motion 500A by the facing magnetic fields 300A. Thus, plasma density can be increased.

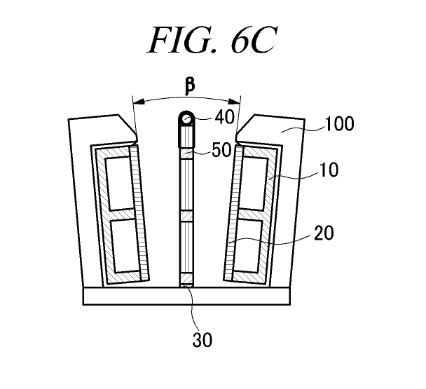

Referring to FIG. 7, the external polarity section 11 of one of the pair of magnetic field generating units 10 may have a shape where its surface facing the other magnetic field generating unit 10 forms a closed loop. By way of example, the external polarity section 11 may have a rectangular shape, or a track shape (or an elliptical shape) as shown in FIG. 7.

Further, the internal polarity section 13 of one magnetic field generating units 10 may have a shape where its surface facing the other magnetic field generating unit forms a straight line as illustrated in FIG. 7(a) or a closed loop as illustrated in FIG. 7(b).

In case that the internal polarity section 13 has a closed loop shape, the internal polarity section 13 may have a rectangular shape, or a track shape (or an elliptical shape) as depicted in FIG. 7(b).

Each of the external polarity section 11 and the internal polarity section 13 may be composed of a multiple number of magnets.

The interval between the pair of magnetic field generating units 10 is set to allow the facing magnetic fields 300A, which provide a rotational force for rotating electrons, to be formed between the pair of magnetic field generating units 10.

Referring to FIG. 4, the rotational force for rotating electrons means a force which is generated in a direction perpendicular to the direction of the facing magnetic fields 300A according to the Fleming's left hand rule and applied to the electrons so as to allow the electrons to make the rotational motion 500A.

The present plasma enhanced chemical vapor deposition apparatus includes the pair of facing electrodes 20.

The pair of facing electrodes 20 may be arranged to face each other between the pair of magnetic field generating units 10.

If an electric power is applied to the pair of facing electrodes 20, the reaction gas 31 supplied from below the pair of facing electrodes 20 may be dissociated into positive ions and electrons and turn into a plasma state. At this time, a direct current, an alternating current, a super high frequency wave, an electron beam, or the like may be applied to the pair of facing electrodes 20 from a power supply device 80 to be described later.

Here, the arrangement that the pair of facing electrodes 20 face each other may not only imply a configuration where the facing electrodes 20 face in parallel to each other, but may also imply a configuration where the facing electrodes are inclined toward the central magnetic field generating unit 50 within a present angular range.

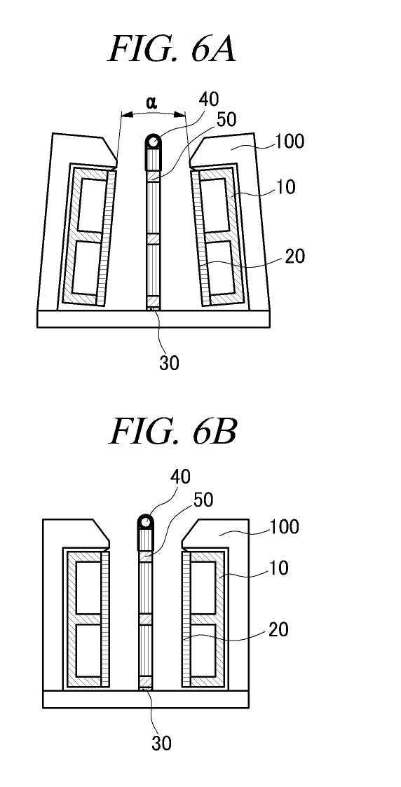

By way of non-limiting example, the pair of facing electrodes 20 may be inclined such that they become closer to the central magnetic field generating unit 50 as it goes upward, as illustrated in FIG. 6(a). Alternatively, the pair of facing electrodes 20 may be inclined such that they become closer to the central magnetic field generating unit as it goes downward, as depicted n FIG. 6(b). Still alternatively, the pair of facing electrodes 20 may be formed so as to be in parallel to the central magnetic field generating unit 50, as shown in FIG. 6(c).

The pair of facing electrodes 20 may be arranged within the mounting unit 100.

Further, the pair of facing electrodes 20 may be arranged such that the facing magnetic fields 300A pass therebetween. By way of example, but not limitation, each facing electrode 20 may be arranged on the external polarity section 11 and the internal polarity section 13, as shown in FIGS. 2 and 8.

With this configuration, as soon as the reaction gas 31 is dissociated into the positive ions and the electrons in the plasma state by a super high frequency wave or the like applied from the pair of facing electrodes 20, the electrons are allowed to make rotational motions 300A by the facing magnetic fields 300A. Hence, plasma density can be further increased.

The present plasma enhanced chemical vapor deposition apparatus includes a gas supply unit 30.

The gas supply unit 30 may be located between the pair of facing electrodes 20 and supplies the reaction gas 31.

When the reaction gas 32 passes through a space between the pair of facing electrodes 20, the reaction gas 31 receives a super high frequency wave or the like from the facing electrodes 20 and turns into plasma having a function as ionization energy and polymerization energy.

The gas supply unit 30 may be configured to supply the reaction gas 31 to below the pair of facing electrodes 20.

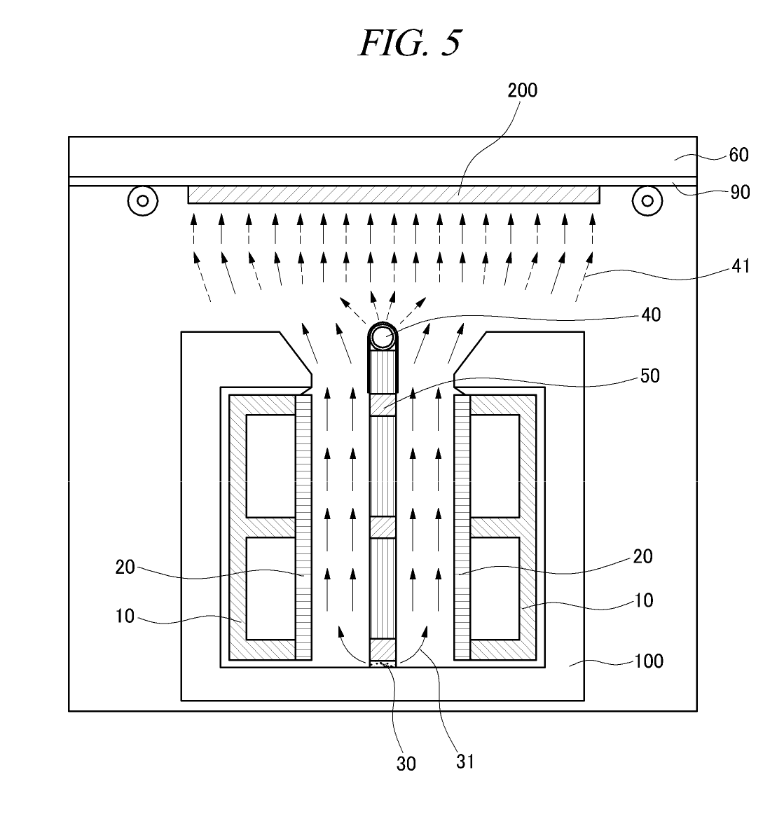

Referring to FIG. 5, after supplied from below, the reaction gas 31 gradually rises upward and turns into a plasma state through the space between the pair of facing electrodes 20. The reaction gas 31 in the plasma state then ionizes precursors 41 supplied from the precursor supply unit 40. A part of the reaction gas 31 in the plasma state may react with the ionized precursors 41 and be deposited on a surface of the coating target object 200.

Further, when supplied from below, the reaction gas 31 may allow the precursors 41 supplied from the precursor supply unit 40 to rise upward. Thus, the precursors 41 can be prevented from being introduced to the facing electrodes 20.

As for the gas supply unit 30, only its discharge port for discharging the reaction gas 31 may be positioned below the pair of facing electrodes 20.

Further, the gas supply unit 30 may be configured to supply the reaction gas 31 while controlling a flow rate of the reaction gas 31 flowing upward from below the facing electrodes 20 to be uniform.

If the flow rate of the reaction gas 31 that flows upward from below is uniform, the density of plasma generated by the dissociation of the reaction gas 31 may be maintained uniform, so that a thin film can be deposited uniformly.

The gas supply unit 30 may be located under the central magnetic field generating unit 50.

In such a configuration, since it becomes needless to provide the gas supply unit 30 as a separate component from the central magnetic field generating unit 50, compact space use is enabled, and, thus, the entire scale of the whole equipment can be reduced, and the required number of vacuum pump 70 can also be greatly reduced.

Here, only the discharge port of the gas supply unit for discharging the reaction gas 31 may be positioned under the central magnetic field generating unit 50.

The present plasma enhanced chemical vapor deposition apparatus 40 includes the precursor supply unit 40.

The precursor supply unit 40 may be provided between the pair of facing electrodes 20 and supplies the precursors 41.

The precursor 41 refers to a matter that precedes a certain matter in a metabolism or a reaction, or precedes a finally obtainable matter.

The precursors 41 may be ionized by the plasma which functions as ionization energy. The ionized precursor 41 may make a physical or chemical reaction with the reaction gas 31 in the plasma state and be deposited on a surface of the coating target 200.

To elaborate, referring to FIG. 5, the precursors 41 are ionized by the reaction gas 31 that is supplied from below and excited into the plasma state as a result of receiving a super high frequency wave or the like from the facing electrodes 20. The ionized precursors 41 may rise upward along with the reaction gas 31 in the plasma state, thus being prevented from flowing to the facing electrodes 20. Concurrently, the ionized precursors 41 may react with a part of the reaction gas 31 in the plasma state and be deposited on a surface of the coating target 200 located thereabove.

The precursor supply unit 40 may be positioned above the central magnetic field generating unit 50.

In such a configuration, since it becomes needless to provide the precursor supply unit 40 as a separate component from the central magnetic field generating unit 50, compact space use is enabled, and, thus, the entire scale of the whole equipment can be reduced, and the number of vacuum pumps 70 required can also be greatly reduced.

Further, since the precursors 41 are raised upward together with the reaction gas 31 supplied from below, inflow of the precursors 41 to the facing electrodes 20 can be suppressed.

The precursor supply unit 40 may be positioned at an upper end of the central magnetic field generating unit 50, as illustrated in FIGS. 1 to 7 and FIG. 9.

Here, only a discharge port of the precursor supply unit 40 for discharging the precursor 41 may be positioned above the central magnetic field generating unit 50.

Further, the precursor supply unit 40 may be configured to supply the precursor 41 to a height position equal to or higher than the upper ends of the pair of facing electrodes 20.

If the precursor supply unit 40 is located at a height position lower than the upper ends of the pair of facing electrodes 20, the precursors 41 may be flown to the pair of facing electrodes 20, resulting in contamination of the facing electrodes 20. Furthermore, maximizing the plasma density as stated above cannot be achieved.

Especially, even if the precursors 41 can be raised upward by the reaction gas 31 supplied from below, if the precursors 41 are supplied at a height position lower than the upper ends of the facing electrodes 20, a part of the supplied precursors 41 may be introduced to the facing electrodes 20. If, however, the precursors 41 are supplied at the height position equal to or higher than the upper ends of the facing electrodes 20, inflow of the precursors 41 to the facing electrodes 20 can be avoided fundamentally.

The precursors 41 are deposited on the surface of the coating target 200 located above them by being ionized by the reaction gas 31 in the plasma state supplied from below. At this time, the higher the plasma density is, the higher the ionization rate of the precursors may be, thus increasing deposition efficiency for a thin film. Since the plasma density tends to be highest between the pair of facing electrodes 20, it may be desirable to supply the precursors 41 to a height position equal to or higher than the upper ends of the facing electrodes 20 and, also, as close to the upper ends of the facing electrodes 20 as possible. In this way, ionization of the precursors can be maximized.

In short, in order to increase the ionization rate of the precursors 41 while concurrently excluding the inflow of the precursors 41 to the facing electrodes 20, it may be desirable that the precursor supply unit 40 is configured to supply the precursors 41 to a height position equal to or higher than and closest to the upper ends of the pair of facing electrodes 20.

By way of example, the precursor supply unit 40 may be configured to supply the precursors 40 to a position equal to the height position of the upper ends of the pair of facing electrodes 20. Alternatively, as illustrated in FIGS. 1 to 9, the precursor supply unit 40 may be configured to supply the precursors 41 to a height position higher than the upper ends of the pair of facing electrodes 20.

The present plasma enhanced chemical vapor deposition apparatus includes the central magnetic field generating unit 50.

The central magnetic field generating unit 50 may be provided between the pair of facing electrodes 20.

The central magnetic field generating unit 50 may be provided such that a continuous flow of facing magnetic fields 300A is formed, as depicted in FIG. 2, or such that a discontinuous flow of the facing magnetic fields 300A is formed, as shown in FIG. 8.

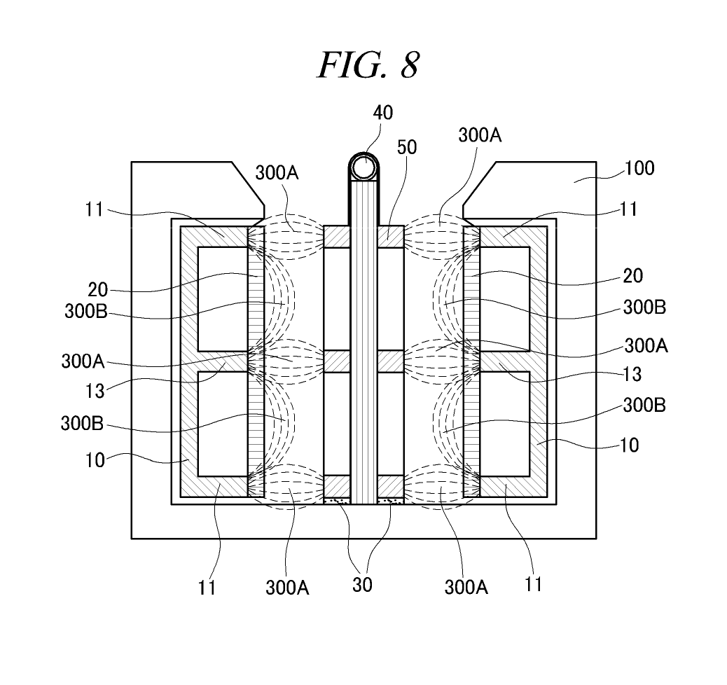

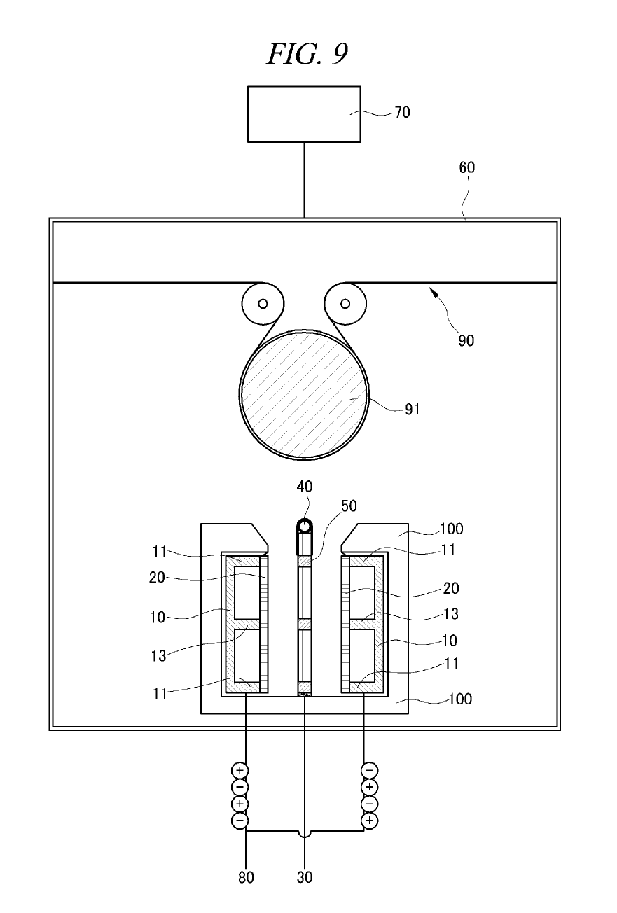

By way of example, the central magnetic field generating unit 50 provided as depicted in FIG. 2 may include three magnets arranged as shown in FIG. 10(a). In such a configuration, since the three magnets only need to be arranged with a vertical gap therebetween, the central magnetic field generating unit 50 can be manufactured through a simple process.

In such a configuration, however, as illustrated in FIG. 10(a), the polarities of the external polarity section and the internal polarity section 13 of one magnetic field generating unit 10 are opposite to the polarities of the external polarity section 11 and the internal polarity section 13 of the other magnetic field generating unit 10, as shown in FIG. 10(a). Thus, it is required to manufacture the pair of magnetic field generating units 10 differently.

That is, in the configuration of providing the central magnetic field generating unit 50 as depicted in FIG. 2, an additional process for manufacturing the pair of magnetic field generating units 10 differently may be required, though the manufacturing process for the central magnetic field generating unit 50 is simple.

As another example, the central magnetic field generating unit 50 provided as illustrated in FIG. 8 may include six magnets arranged as shown in FIG. 10(b). In this configuration, in case that a left magnet and a right magnet are arranged with their same magnetic poles facing each other, as shown in FIG. 10(b), it may be desirable to provide a ferromagnetic substance between the left and right magnets.

In such a case, the polarities of the external polarity section 11 and the internal polarity section 13 of one magnetic field generating unit 10 are identical to the polarities of the external polarity section 11 and the internal polarity section 13 of the other magnetic field generating unit 10, as shown in FIG. 10(b). Thus, it is not required to manufacture the pair of magnetic field generating units 10 differently.

That is, in the configuration where the central magnetic field generating unit 50 is located as depicted in FIG. 8, although an additional process for providing ferromagnetic substances between the left magnets and the right magnets of the central magnetic field generating unit 50 is required, the pair of magnetic field generating units 10 can be manufactured through the same process.

The position and the configuration of the central magnetic field generating unit 50 may not be limited to the examples shown in FIGS. 1 to 10. The central magnetic field generating unit 50 can be placed at any position as long as it is located between the pair of facing electrodes 20 and facing magnetic fields 300A can be formed between the central magnetic field generating unit 50 and each of the magnetic field generating units 10.

The central magnetic field generating unit 50 may be configured to generate facing magnetic fields 300A between it and each of the magnetic field generating units 10.

Further, the central magnetic field generating unit 50 may be provided such that it faces each of the pair of magnetic field generating units 10 with opposite polarities adjacent to each other.

Under the presence of the central magnetic field generating unit 50, facing magnetic fields 300A are formed between each of the magnetic field generating units 10 and the central magnetic field generating unit 50, and lateral magnetic fields 300B are formed between the external polarity section 11 and the internal polarity section 13 of each magnetic field generating unit 10. Accordingly, in the configuration where the central magnetic field generating unit 50 is provided in addition to the pair of magnetic field generating units 10, a magnetic flux density increases higher than that in case of forming both the facing magnetic fields 300A and the lateral magnetic fields 300B only with the pair of magnetic field generating units 10. Thus, as compared to a case of providing only the single pair of magnetic field generating units 10, higher magnetic fields 300A can be formed.

That is, by providing the central magnetic field generating unit 50, higher facing magnetic fields 300A can be formed, so that the strength of a force applied to electrons may be increased, accelerating the rotational motions 500A. As a consequence, the plasma density can be further enhanced.

In short, the present plasma enhanced chemical vapor deposition apparatus is capable of increasing plasma density by forming both the facing magnetic fields 300A and the lateral magnetic fields 300B through the use of only the pair of magnetic field generating units 10 or through the use of the central magnetic field generating unit 50 as well as the pair of magnetic field generating units 10. Thus, an ionization rate of the precursors 41 and a coupling rate between the ionized precursors 41 and a part of the reaction gas 31 in the plasma state can be increased, leading to an increase of deposition efficiency for a thin film.

The present plasma enhanced vapor deposition apparatus includes the vacuum chamber 60.

In order to minimize introduction of foreign substances into a thin film, it may be desirable to perform the thin film deposition process in the vacuum chamber 60.

The present plasma enhanced vapor deposition apparatus includes the vacuum pump 70.

The vacuum pump 70 serves to depressurize the inside of the vacuum chamber 60 into a vacuum state.

The vacuum pump 70 exhausts the reaction gas 31 and by-products of the precursors remaining in the vacuum chamber 60 to the outside through an exhaust port, thus turning the inside of the vacuum chamber 60 into a vacuum.

The vacuum pump 70 may be configured to maintain a vacuum level of the inside of the vacuum chamber 60 at a vacuum level required in a sputtering process.

In a conventional plasma enhanced chemical vapor deposition apparatus having low deposition efficiency, the vacuum level of the vacuum chamber 60 needs to be maintained a high vacuum level by exhausting by-products out of the vacuum chamber 60 in an maximum amount.

In the present plasma enhanced chemical vapor deposition apparatus, however, since the plasma density is increased by generating the facing magnetic fields 300A and the lateral magnetic fields 300B, high deposition efficiency may be obtained even when the vacuum level of the vacuum chamber 60 is maintained a lower vacuum level than that of the conventional apparatus.

That is, unlike in the conventional plasma enhanced chemical vapor deposition apparatus, the vacuum chamber 60 of the present plasma enhanced chemical vapor deposition apparatus can be maintained at a low vacuum level as required in a sputtering process by means of the vacuum pump 70. Thus, plasma-enhanced chemical vapor deposition and sputtering can be performed in the single chamber, and the range of application of the equipment can be enlarged.

The present plasma-enhanced chemical vapor deposition apparatus includes the power supply device 80.

In general, in order to excite a gas into plasma, a direct current, an alternating current, a super high frequency wave, an electron beam, or the like is applied to the gas. In this regard, the power supply device 80 may be configured to apply a direct current, an alternating current, a super high frequency wave, an electron beam, or the like to the pair of facing electrodes 20.

The power supply device 80 may be configured to generate an alternating current.

In such a case, an alternating current is applied to the pair of facing electrodes 20. Positive ions and electrons, which are generated as the reaction gas 31 is excited into a plasma state, are allowed to flow in the facing electrodes 20 alternately. Accordingly, re-coupling of the positive ions and the electrons can be suppressed, so that plasma density can be increased.

That is, as the power supply device 80 generates an alternating current, the plasma density can be increased, which results in improvement of deposition efficiency for a thin film.

The present plasma enhanced chemical vapor deposition apparatus includes the moving unit 90.

The moving unit 90 is configured to move the coating target 200.

By way of non-limiting example, referring to FIGS. 1, 5 and 9, the moving unit 90 has a roller and is capable of moving the coating target 200.

The moving unit 90 may also be configured to supply the coating target 200 into the vacuum chamber 60.

Further, the moving unit 90 may be configured to move the coating target 200 supplied into the vacuum chamber 60.

The reaction gas 31 is supplied upward from below the space between the pair of facing electrodes 20, and the precursors 41 are supplied from the precursor supply unit 40 provided between the pair of facing electrodes 20 and are raised by the reaction gas 31 in the plasma state. Thus, the moving unit 90 may be configured to move the coating target 200, on which a thin film is to be deposited, to above the space between the pair of facing electrodes 20.

Further, the moving unit 90 may be configured to unload the coating target 200 once loaded into the vacuum chamber 60 to the outside of the vacuum chamber 60.

Since the moving unit 90 needs to be installed so as to be capable of moving the coating target 200 from the outside of the vacuum chamber 60 to the inside thereof or from the inside of the vacuum chamber 60 to the outside thereof, the vacuum chamber 60 may have a hole or the like for the moving unit 90.

In a conventional plasma enhanced chemical vapor deposition apparatus, a vacuum level within a vacuum chamber needs to be maintained high in order to obtain high deposition efficiency. Thus, a thin film deposition process is performed in a completely airtight vacuum chamber 60. For the reason, a thin film is formed in a hermetically sealed vacuum chamber while holding a coating target 200 at a fixed position.

However, in the present plasma enhanced chemical vapor deposition apparatus, since the plasma density is increased by generating the facing magnetic fields 300A and the lateral magnetic fields 300B as described above, the present apparatus may be capable of achieving the thin film deposition efficiency as obtained in the conventional apparatus even when the vacuum chamber 60 is maintained at a vacuum level lower than that in the conventional apparatus.

Accordingly, a hole or the like can be formed at the vacuum chamber 60 for the moving unit 90, and the coating target 200 can be moved between the inside and the outside of the vacuum chamber 60. Thus, a thin film deposition process can be performed more efficiently.

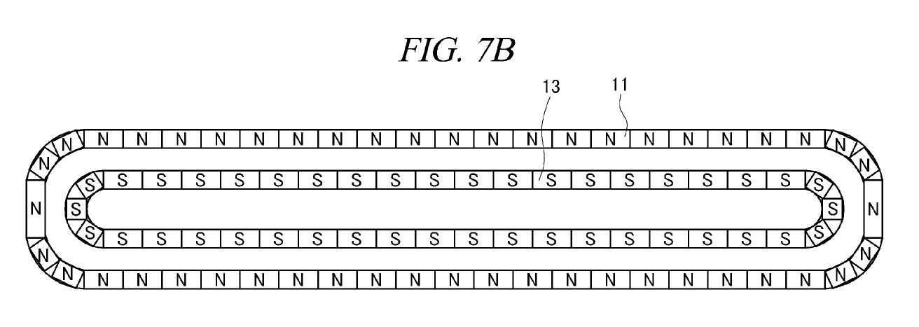

Further, referring to FIG. 9, the moving unit 90 may include a sub-roll 91, and a bias may be applied to the sub-roll 91. In this way, by applying the bias to the coating target 200 through the sub-roll 91, a coating can adhere to the coating target 200 more strongly, so that the coating film can be densified.

By way of non-limiting example, as shown in FIG. 9, the sub-roll 91 may be positioned above the precursor supply unit 40 and the gas supply unit 30 in order to further improve deposition efficiency for a thin film.

The present plasma enhanced chemical vapor deposition apparatus generates facing magnetic fields 300A between the pair of magnetic field generating units 10 or between the central magnetic field generating unit 50 and the pair of magnetic field generating units 10. Further, the present plasma enhanced chemical vapor deposition apparatus also generates lateral magnetic fields 300B between the external polarity section 11 and the internal polarity section 13 of each magnetic field generating unit 10. The facing magnetic fields 300A and the lateral magnetic fields 300B allow electrons to make rotational motion 500A and hopping motion 500B infinitely. Accordingly, an ionization rate of the reaction gas 31 into a plasma state is increased, and plasma density is increased. Since plasma increases reactivity of a matter, as the plasma density increases, an ionization rate of precursors 41 and a coupling rate between the ionized precursors 41 and a part of the reaction gas 31 in the plasma state can be increased. As a result, deposition efficiency for a thin film can be improved.

Besides, by applying an alternating current from the power supply device 80 and controlling a flow rate of the upwardly flowing reaction gas 31 to be uniform, introduction of the precursors 41 into the facing electrodes 20 can be suppressed. Thus, the deposition efficiency for a thin film can be ameliorated.

Moreover, unlike a conventional apparatus, the present plasma enhanced chemical vapor deposition apparatus is capable of moving the coating target 200 to the inside or the outside of the vacuum chamber 60 by means of the moving unit 90. Thus, a thin film deposition process can be performed more efficiently.

In addition, since the plasma enhanced chemical vapor deposition apparatus exhibits high deposition efficiency for a thin film, the vacuum chamber 60 need not be maintained at a high vacuum level, as compared to a conventional apparatus, but can be maintained at a low vacuum level as required in a sputtering process. Thus, a sputtering process and a plasma enhanced chemical vapor deposition process can be performed in the singe vacuum chamber 60 at the same time. Accordingly, the present plasma enhanced chemical vapor deposition may have a wide range of applications.

Further, in the present plasma enhanced chemical vapor deposition apparatus, it is possible to set up a configuration where the precursor supply unit 40 is located above the central magnetic field generating unit 50 and the gas supply unit 30 is located under the central magnetic field generating unit 50. Through this compact space utilization, the overall size of the entire equipment can be reduced, and the required number of the vacuum pump 70 can be greatly reduced.

Further, the present plasma enhanced chemical vapor deposition apparatus supplies the reaction gas 31 from below and thus is capable of suppressing introduction of precursors 41 to the facing electrodes 20. At this time, by disposing the precursor supply unit 40 at a height position equal to or higher than and closest to upper ends of the facing electrodes 20, introduction of the precursors 41 to the facing electrodes 20 can be avoided fundamentally, and an ionization of the precursors 41 can be increased, leading to improvement of the deposition efficiency for a thin film. Besides, by controlling the flow rate of the reaction gas 31 to be uniform, the plasma density can be maintained uniform, so that the thin film can be formed uniformly. That is, the present plasma enhanced chemical vapor deposition apparatus is capable of achieving both high deposition efficiency for the thin film and high uniformity of the thin film.

The above description of the illustrative embodiments is provided for the purpose of illustration, and it would be understood by those skilled in the art that various changes and modifications may be made without changing technical conception and essential features of the illustrative embodiments. Thus, it is clear that the above-described illustrative embodiments are illustrative in all aspects and do not limit the present disclosure. For example, each component described to be of a single type can be implemented in a distributed manner. Likewise, components described to be distributed can be implemented in a combined manner.

The scope of the inventive concept is defined by the following claims and their equivalents rather than by the detailed description of the illustrative embodiments. It shall be understood that all modifications and embodiments conceived from the meaning and scope of the claims and their equivalents are included in the scope of the inventive concept.

We claim:

1. A plasma enhanced chemical vapor deposition apparatus for depositing a thin film on a surface of a coating target in a vacuum chamber, the apparatus comprising:
a pair of magnetic field generating units arranged to face each other with a gap therebetween;
a pair of facing electrodes arranged to face each other between the pair of magnetic field generating units;
a gas supply unit configured to supply a reaction gas into a space between the pair of facing electrodes; and
a precursor supply unit configured to supply a precursor into the space between the pair of facing electrodes,
wherein a facing magnetic field is formed between the pair of magnetic field generating units.

2. The plasma enhanced chemical vapor deposition apparatus of claim 1,
wherein each of the pair of magnetic field generating units includes an internal polarity section and an external polarity section surrounding the internal polarity section, and
a polarity of the external polarity section is opposite to a polarity of the internal polarity section.

3. The plasma enhanced chemical vapor deposition apparatus of claim 1 or 2,
wherein the pair of magnetic field generating units is arranged such that opposite polarities thereof face each other.

4. The plasma enhanced chemical vapor deposition apparatus of claim 1,
wherein the gap is a spatial interval set to allow the facing magnetic field, which provides a rotational force for an electron, to be formed between the pair of magnetic field generating units arranged to face each other.

5. The plasma enhanced chemical vapor deposition apparatus of claim 1,
wherein the pair of facing electrodes is arranged such that the facing magnetic field passes therebetween.

6. The plasma enhanced chemical vapor deposition apparatus of claim 1,
wherein the gas supply unit supplies the reaction gas from below the pair of facing electrodes.

7. The plasma enhanced chemical vapor deposition apparatus of claim 6,
wherein the gas supply unit supplies the reaction gas while controlling a flow rate of the reaction gas flowing upward from below the pair of facing electrodes to be uniform.

8. The plasma enhanced chemical vapor deposition apparatus of claim 1 or 2, further comprising:
a central magnetic field generating unit between the pair of facing electrodes,
wherein the central magnetic field generating unit is configured to form a magnetic field between itself and each of the pair of magnetic field generating units.

9. The plasma enhanced chemical vapor deposition apparatus of claim 8,
wherein the central magnetic field generating unit is disposed such that opposite polarities face each other between itself and each of the pair of magnetic field generating units.

10. The plasma enhanced chemical vapor deposition apparatus of claim 8,
wherein the precursor supply unit is provided above the central magnetic field generating unit.

11. The plasma enhanced chemical vapor deposition apparatus of claim 8,
wherein the gas supply unit is provided below the central magnetic field generating unit.

12. The plasma enhanced chemical vapor deposition apparatus of claim 1,
wherein the precursor supply unit is configured to supply the precursor to a height position equal to or higher than upper ends of the pair of facing electrodes.

13. The plasma enhanced chemical vapor deposition apparatus of claim 1, further comprising:
the vacuum chamber; and
a vacuum pump configured to depressurize an inside of the vacuum chamber into a vacuum state.

14. The plasma enhanced chemical vapor deposition apparatus of claim 13,
wherein the vacuum pump maintains the inside of the vacuum chamber at a vacuum level required in a sputtering process.

15. The plasma enhanced chemical vapor deposition apparatus of claim 1, further comprising:
a power supply device configured to apply a power to the pair of facing electrodes,
wherein the power supply device generates an AC power.

16. The plasma enhanced chemical vapor deposition apparatus of claim 1, further comprising:
a moving unit configured to move the coating target.

17. The plasma enhanced chemical vapor deposition apparatus of claim 16,
wherein the moving unit loads the coating target into the vacuum chamber and then unloads the coating target from the vacuum chamber.

18. The plasma enhanced chemical vapor deposition apparatus of claim 16,
wherein the moving unit includes a sub-roll, and
a bias is applied to the sub-roll.
